(19) United States
(12) Patent Application Publication
(10) Pub. No.: US 2018/0088627 A1
(43) Pub. Date: Mar. 29, 2018

(54) INTERCONNECTS FOR WEARABLE DEVICE

(71) Applicants: Bok Eng Cheah, BUKIT GAMBIR (MY); Boon Ping Koh, Seberang Jaya (MY); Kooi Chi Ooi, Glugor (MY); Jackson Chung Peng Kong, Tanjung Tokong (MY)

(72) Inventors: Bok Eng Cheah, BUKIT GAMBIR (MY); Boon Ping Koh, Seberang Jaya (MY); Kooi Chi Ooi, Glugor (MY); Jackson Chung Peng Kong, Tanjung Tokong (MY)

(21) Appl. No.: 15/280,994

(22) Filed: Sep. 29, 2016

(51) Int. Cl. G06F 1/16; H05K 1/03; H05K 1/02; H05K 1/18; H01L 23/538; H01L 25/065; H01L 25/00; H05K 3/30; H05K 3/46; H01L 23/00; H05K 3/28; H01L 23/66

(52) U.S. Cl. CPC G06F 1/163; H01L 2223/6627; H05K 1/0393; H05K 1/0237; H05K 1/189; H01L 23/5386; H01L 23/5387; H01L 25/0655; H01L 25/50; H05K 3/303; H05K 3/4644; H05K 1/0298; H01L 23/5383; H01L 23/564; H05K 3/28; H01L 23/66; H05K 2203/16; H05K 1/038

(57) ABSTRACT

Various embodiments disclosed relate to a wearable electronic device. One embodiment includes of a wearable electronic device includes a first flexible layer. The first flexible layer includes a first surface and a second surface that is substantially parallel to the first surface. A first electrical component and a second electrical component is attached to the second surface. A transmission line connects the first electrical component and the second electrical component. A voltage reference trace connected to a voltage reference source attached to at least one of the first electrical component or the second electrical component. The device further includes a second flexible layer. The second flexible layer includes a third surface that is substantially parallel to the second surface and facing the second surface. The second flexible layer also includes a fourth surface. The device further includes a voltage reference plane attached to the third surface. An interconnection is formed between the voltage reference trace and the voltage reference plane.

### BACKGROUND

Wearable electronic systems typically include components that are capable of transmitting and receiving a signal. To ensure optimal performance of the device auxiliary components are added to the device. However, some of these auxiliary devices may be large or heavy which makes the wearable device less desirable to a user and makes it more difficult to incorporate the device into a product such as an article of clothing or a patch.

### BRIEF DESCRIPTION OF THE FIGURES

In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

FIG. 1 is a sectional schematic view of a wearable electronic device, in accordance with various embodiments.

FIG. 2 is a bottom schematic view of the wearable electronic device in accordance with various embodiments.

FIG. 3 is a sectional schematic view of another embodiment of the wearable electronic device in accordance with various embodiments.

FIGS. 4A-4F are schematic diagrams illustrating a method of forming the wearable electronic device in accordance with various embodiments.

FIG. 5 is a system level diagram of a system including the wearable electronic device, according to various embodiments.

### DETAILED DESCRIPTION OF THE INVENTION

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts may be carried out in any order without departing from the principles of the invention, except when a temporal or operational sequence is explicitly recited. Furthermore, specified acts may be carried out concurrently unless explicit claim language recites that they be carried out separately. For example, a claimed act of doing X and a claimed act of doing Y may be conducted simultaneously within a single operation, and the resulting process will fall within the literal scope of the claimed process.

The term “about” as used herein may allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999%, or more, or 100%.

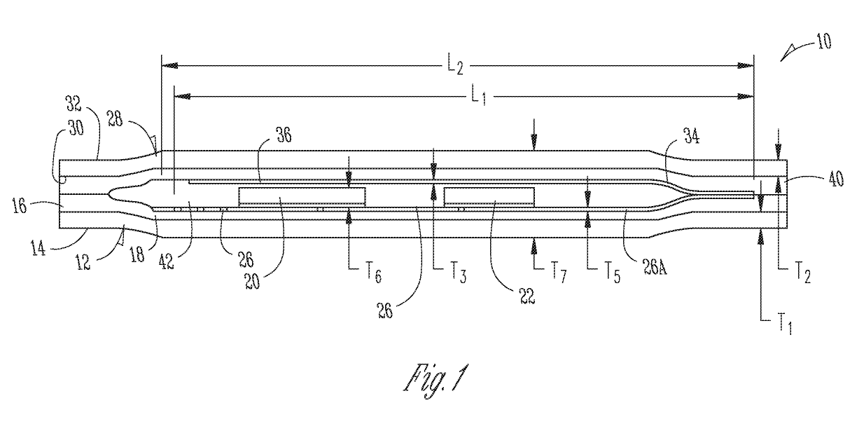

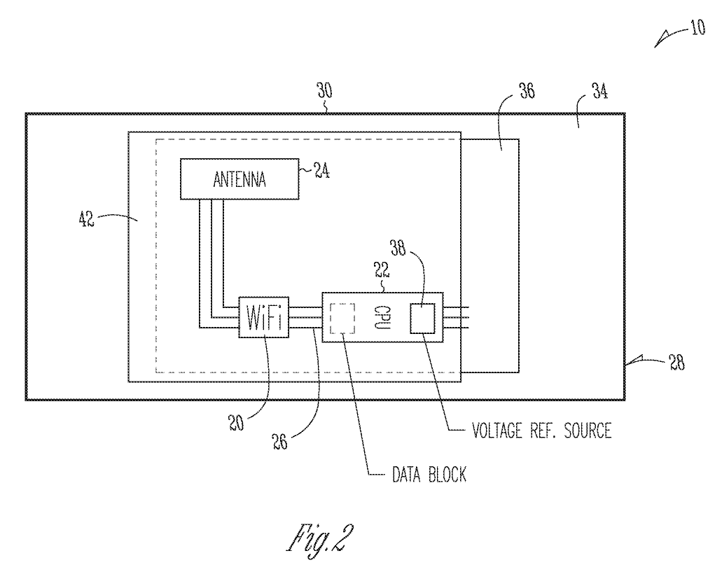

FIGS. 1 and 2 illustrate a wearable electronic device. Specifically FIG. 1 illustrates a sectional view of the wearable device and FIG. 2 illustrates a bottom view of the wearable electronic device. FIGS. 1 and 2 illustrate many of the same components and reference will be made to either FIG. 1 or FIG. 2 throughout the description of this embodiment.

As shown in FIG. 1, wearable electronic device 10 includes first flexible layer 12. First flexible layer 12 includes first surface 14 and opposite second surface 16. First surface 14 and second surface 16 generally mirror each other in that they run substantially parallel to one another. First surface 14 and second surface 16 define a thickness t₁ of first flexible layer 12. First flexible layer 12 is made from a material that is flexible and may adapt to movement by a wearer. That is, first flexible layer 12 may stretch or contract when external stresses from the movement or a wearer are applied to first flexible layer 12. The specific material that first flexible layer 12 is made from may vary and may be selected based on a specific application. For example, first flexible layer 12 may be made from a fabric material or a textile material. Generally, a fabric material may be a material made through weaving, knitting, spreading, crocheting, or bonding. A textile material may generally refer to a material made from interlacing fibers. First flexible layer 12 may be made of either of these materials and additionally in some examples first flexible layer 12 may be formed from a mixture of fabric materials and textile materials.

First water resistant encapsulant layer 18 is attached to second surface 16 of first flexible layer 12. First flexible layer 12 may include pores in the fabric or textile material that could allow water to enter the interior of wearable electronic device 10. First water resistant encapsulant layer 18, however, may help to substantially prevent water from penetrating through first flexible layer 12. First water resistant encapsulant layer 18 is formed from a water resistant material. There are many suitable water resistant materials that first water resistant encapsulant layer may be made from. Suitable materials may include silicone elastomers, fluoropolymers, rubbers, polyvinyl chloride, polyurethane, wax, and combinations thereof. One consideration driving the selection of the water resistant material is whether the material would increase the stiffness of wearable device 10. If the water resistant material is too stiff, then user comfort may be compromised by the selection of the material.

First silicon die 20 is indirectly attached to second surface 16 of first flexible layer 12 by way of first water resistant encapsulant layer 18. In some examples, a section of first water resistant encapsulant layer 18 may be cut out to allow first silicon die 20 to directly attach to second surface 16. In other examples a different intermediate layer may be present between first silicon die 20 and second surface 16 so that first silicon die 20 may be directly attached to second surface 16. Second silicon die 22 is similarly attached to second surface 16. As shown in FIG. 2 wearable electronic device 10 may include additional silicon dies such as third silicon die 24.

First silicon die 20, second silicon die 22, and third silicon die 24 may be electrical components of wearable electronic device 10. The electronic component that each die is selected from may be driven by considerations relating to the desired capabilities of device 10. Suitable examples of electronic components represented by dies 20, 22, and 24 may include any one of a central processing unit, a flash memory, a wireless charger, a power management integrated circuit (PMIC), a Wi-Fi transmitter, and a global positioning system.

First silicon die 20, second silicon die 22, and third silicon die 24 may be connected in series by transmission line 26. Transmission line 26 may be formed from a conductive material. Suitable conductive materials include a metal or conductive ink. As shown in FIG. 2, transmission line 26 may further include three wires that transmit an electrical signal between dies 20, 22, and 24. Though not illustrated in the FIG. 1 or 2 transmission line 26 may be configured to connect to an external power source in order to charge wearable device 10. For example, transmission line 26 may be configured to connect to a wired charging system or to an electronic component to support wireless charging.

Wearable electronic device 10 further includes second flexible layer 28. Second flexible layer 28 includes third surface 30 and fourth surface 32, which define a thickness t2 of second flexible layer 28. Third surface 30 and fourth surface 32 generally mirror each other in that they run substantially parallel to one another. Similar to first flexible layer 12, second flexible layer 28 is made from a flexible material such as a fabric or a textile or a combination of those materials. The material that first flexible layer 12 and second flexible layer 28 are made of may be the same material or a different material. One reason to form first flexible layer 12 and second flexible layer 28 from different materials may be to impart different flexibilities to each layer in order to accommodate specific movements or a wearer.

Second water resistant encapsulant layer 34 is attached to third surface 30 of second flexible layer 28. Second water resistant encapsulant layer 34 is made from a water resistant material such as those described herein with respect to first water resistant encapsulant layer 18.

Voltage reference plane 36 is attached to the third surface 30 of second flexible layer 28 by way of second water resistant encapsulant layer 34. In some examples, a section of second water resistant encapsulant layer 34 may be cut out to allow voltage reference plane to directly contact third surface 30. In other examples a different intermediate layer may be present between voltage reference plane 36 and third surface 30.

Voltage reference plane 36 is a conductive layer which associates to a constant voltage level e.g. ground (Vss) or power (Vcc) sources. Reference voltage plane 36 may have a reference voltage ranging up to 5 V. In other embodiments, voltage reference plane 36 may have reference voltage of 0 V, 0.2 V, 0.5 V 1.0 V, 1.8 V and 3.3 V. Voltage reference plane 36 facilitates electric current return path during signal transmissions. In other embodiments, voltage reference plane 36 may exist in the form of signal traces with physical geometry similar to transmission line 26 instead of a large or continuous plane.

Voltage reference plane 36 is generally formed from a conductive material. Suitable conductive materials include a metal or a conductive ink. Voltage reference plane 36 may be configured to ground (Vss) referencing or power (Vcc) referencing depending on the selection of voltage reference source 38. If voltage reference plane 36 is configured to reference to a supply voltage, then the voltage reference source 38 is a Vcc unit. In that case, voltage reference plane 36 is a power reference plane. If voltage reference plane 36 is configured to reference to a ground (Vss), then the voltage reference source 38 is a Vss unit. In that case, voltage reference plane 36 is a ground (Vss) reference plane. Voltage reference source 38 is connected to voltage reference trace 26A and voltage reference plane 36 as shown in FIG. 2. In other words, the voltage reference plane 36 is electrically coupled to the voltage reference source 38 through voltage reference trace 26A. In an embodiment, the voltage reference source 38 forms portion of electrical component such as silicon die 22 in wearable electronic device 10.

Voltage reference trace 26A and voltage reference plane 36 are connected at interconnection 40 formed between the voltage reference trace 26A and the voltage reference plane 36. Interconnection 40 facilitates electrical coupling between the voltage reference source 38 and voltage reference plane 36. Interconnection 40 defines an interface between voltage reference trace 26A and the voltage reference plane 36 such that line 26A and plane 36 directly contact each other. Voltage reference trace 26A and voltage reference plane 36 may be joined in many ways including by thermal compression, low temperature metal diffusion, or by surface activated bonding.

As shown in FIG. 1 a length l₁ of transmission line 26 and electrical components such as silicon die 20 and silicon die 22 are slightly less than a length l₂ of voltage reference plane 36, in other embodiments l₁ and l₂ are substantially equivalent. Thus, a major portion of voltage reference plane 36 is parallel to a major portion of second surface 16 of first flexible layer 12. This allows for the major portion of voltage reference plane 36 to cover at least a portion of second surface 16 of first flexible layer 12. This portion of second surface 16 may include the first silicon die 20, second silicon die 22, and the transmission line 26. As will be described further, this allows for improved signal integrity and signal routing density in wearable electronic device 10 through enhanced current return path, electromagnetic shielding and signal trace impedance control.

In some examples, voltage reference plane 36 has a continuous structure. Alternatively in some examples voltage reference plane may have a discontinuous structure across voltage reference plane. For example, voltage reference plane 36 may include a cut out section. The cut out is sized to allow a portion of at least one of the first silicon die 20, second silicon die 22, or third silicon die 24 to at least partially exposed through the cut out. Typically this may be desirable when silicon dies 20, 22, or 24 have transmitting capabilities. As an example dies that have transmitting capabilities may include a WiFi, a radio transmitter, a wireless charger or a GPS.

Dielectric layer 42 is disposed between first flexible layer 12 and second flexible layer 28. More specifically dielectric layer abuts first silicon die 20, second silicon die 22, third silicon die 24, transmission line 26, voltage reference trace 26A and voltage reference plane 36. Dielectric layer 42 is made from a non-conductive material such as a polyimide, a polyimide, a bismaleimide-triazine (BT) resin, epoxy resin, polyurethanes, benzocyclobutene (BCB), or high-density polyethylene (HDPE). Factors that may drive the decision on which material to use may include the impact of the material on the transmission line electrical characteristics (e.g. trace impedance target) and overall flexibility of wearable electronic device 10.

In order to maintain the connection between voltage reference trace 26A and voltage reference plane 36, interconnection 40 is substantially free of any dielectric materials such as dielectric layer 42. In one embodiment, the plurality of voltage reference trace 26A can be merged into a continuous plane.

As illustrated in FIG. 3, which is a sectional view of another embodiment of wearable electronic device 10, device 10 may be configured to include fourth silicon die 44, fifth silicon die 46 and second transmission line 48. As illustrated in FIG. 3 a first face of voltage reference plane 36 faces first silicon die 20, second silicon die 22, third silicon die 24, and transmission line 26, while a second face of voltage reference plane 36 faces fourth silicon die 44, fifth silicon die 46 and second transmission line 48. Second dielectric layer 50 is located between third surface 30 and each of fourth silicon die 44, fifth silicon die 46, and second transmission line 48. Second voltage reference trace 48A and voltage reference plane 36 form second interconnection 52.

Wearable electronic device 10 may be incorporated into many different types of articles. To aid incorporating wearable electronic device into articles, an adhesive may be disposed on at least one of first surface 14 or fourth surface 32. One article that wearable electronic device 10 may be incorporated into may be an article of clothing. The article of clothing may be formed from a fabric material or a textile material. In addition to being adhered to the clothing, wearable electronic device 10 may be integrated into the clothing. For example wearable electronic device 10 may be sewn into the clothing. Wearable electronic device 10 may also be incorporated into a skin patch. The skin patch may be made from a fabric material or a textile material.

Wearable electronic device 10 and the components forming it may be ultra-thin, which may make it easier to incorporate into an article of clothing or a skin patch. For example, a thickness t3 of the voltage reference plane may range from about 10 microns to about 20 microns. Additionally, a thickness t₅ of transmission line 26 may range from about 10 microns to about 12 microns. A thickness t₆ of the any one of the dies may range from about 20 microns to about 40 microns. A total thickness t₇ of wearable electronic device 10 may range from about 50 microns to about 80 microns.

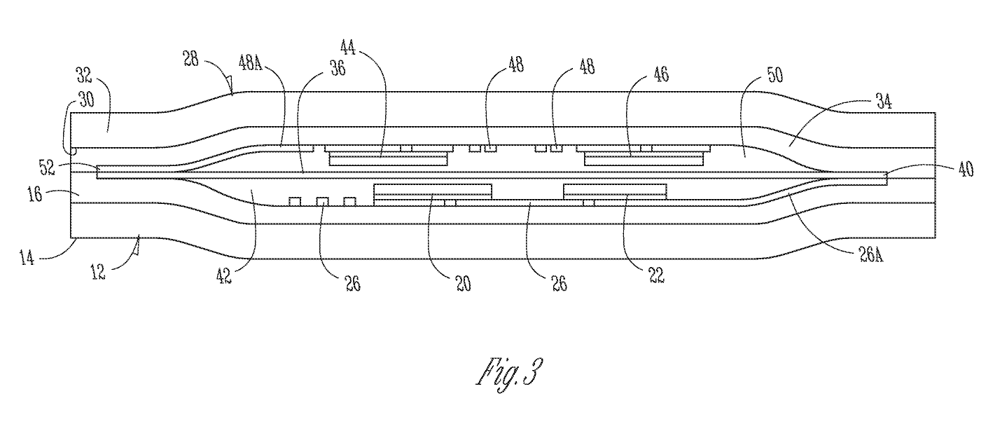

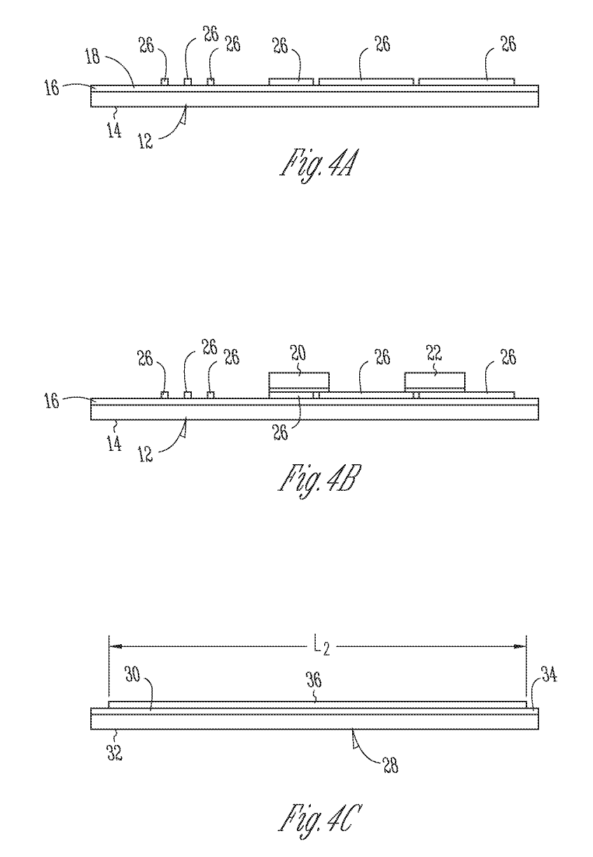

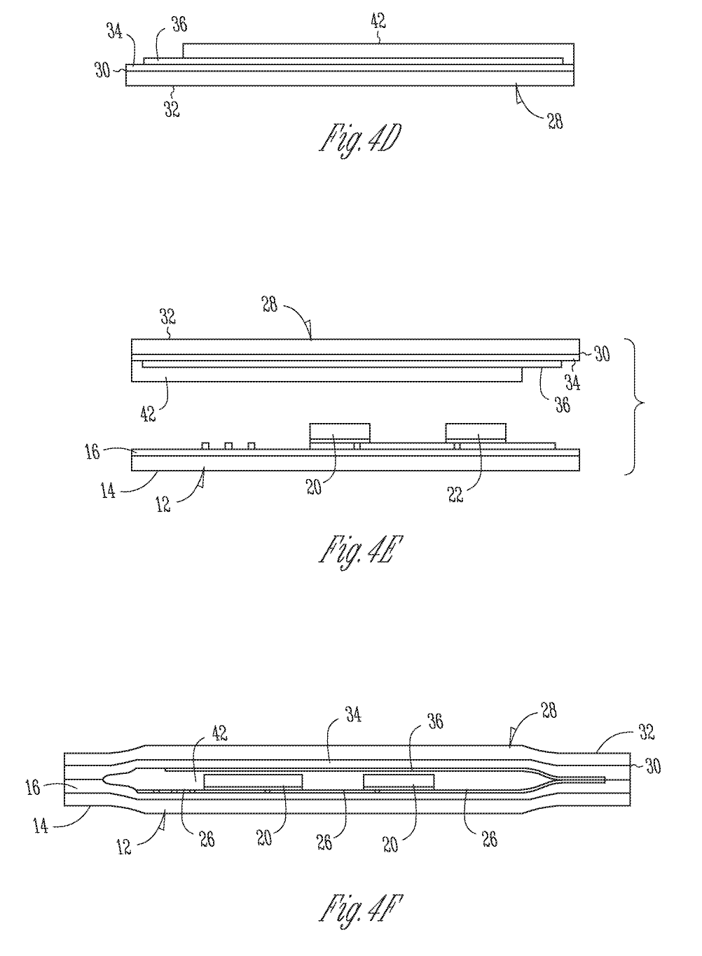

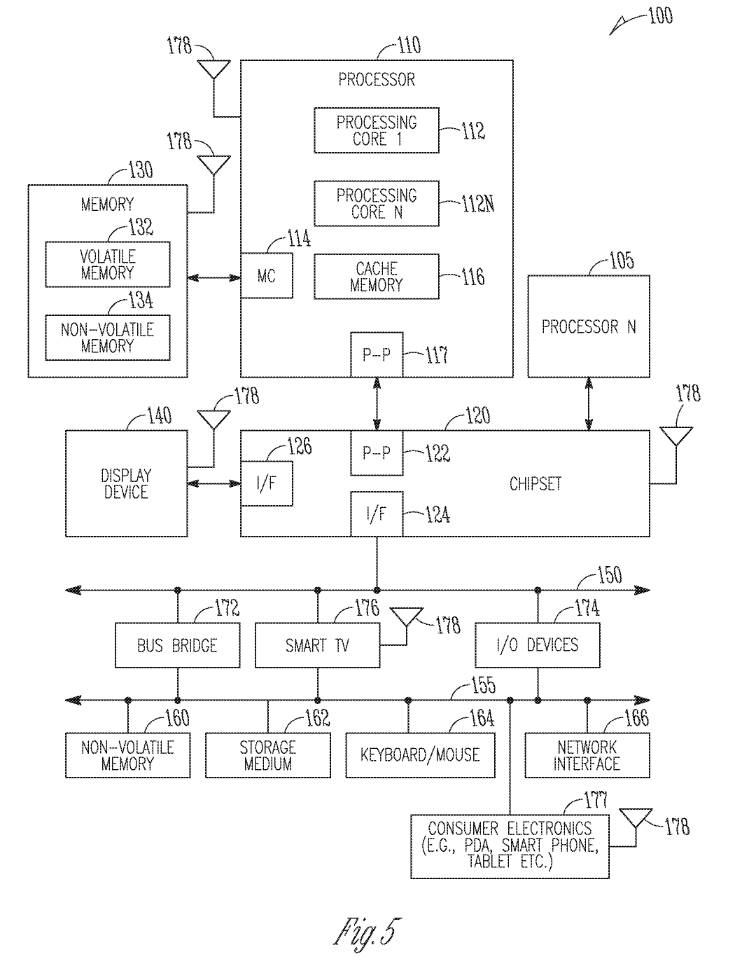

Wearable electronic device 10 may be formed in many different ways. FIGS. 4A-4F illustrate one method of forming device 10. As shown in FIG. 1, first flexible layer 12 is configured to include first water resistant encapsulant layer 18, transmission line 26 and voltage reference trace 26A which are made from a plurality of conductive traces. The plurality of traces are attached to first flexible layer 12 or water resistant encapsulant layer 18 by stamping or metal ink printing.

As illustrated in FIG. 4B, first silicon die 20 and second silicon die 22 are further attached to first flexible layer 12. First silicon die 20 and second silicon die 22 are adhered to first water resistant encapsulant layer 18 between the traces of transmission line 26. Dies 20 and 22 are attached to the traces by low temperature metal diffusion. The temperature at which the low metal diffusion is carried out is typically set to be below the combustion point of the material that first flexible layer 12 is made from. Typically a temperature below 200° F. will suffice.

As illustrated in FIG. 4C, a conductive metal foil (e.g. thin copper foil layer) which is to be configured to a voltage reference plane subsequently such as voltage reference plane 36 is attached to second flexible layer 28. More specifically, second water resistant layer 34 is formed between second flexible layer 28 and voltage reference plane 36, thus layer 34 adheres plane 36 to layer 28. Voltage reference plane 36 may be attached to second flexible layer 28 or second water resistant layer 34 through lamination or stamping process.

As illustrated in FIG. 4D, dielectric layer 42 is attached to a portion of voltage reference plane 36. Thus, a first portion of voltage reference plane 36 is covered by dielectric layer 42 and an adjacent second portion of voltage reference plane 36 is free of the dielectric material. The degree of the total length 12 of voltage reference plane 36 that the first portion of accounts for may vary. For example, the first portion may account for about 80 percent to about 99 percent of voltage reference plane or about 85 percent to about 95 percent of voltage reference plane. Factors that drive the decision as to how much voltage reference plane 36 to the first portion should account for include the desired size of interconnection 40.

As shown in FIG. 4E, first flexible layer 12 and second flexible layer 28 are aligned with each other in order to be joined and form wearable electronic device 10. More specifically, the second portion of voltage reference plane 36 is aligned with one of the plurality of voltage reference traces 26A. This will allow second portion of voltage reference plane 36 to contact one of the traces of voltage reference trace 26A and form interconnection 40.

As shown in FIG. 4F, once the second portion of voltage reference plane 36 is aligned with one of the voltage reference traces 26A, first flexible layer 12 and second flexible layer 28 are compressed together. Compressing first flexible layer 12 and second flexible layer 28 forms interconnection 40 between the second portion of the voltage reference plane 36 and the voltage reference trace 26A. The adhesion of interconnection 40 may be further improved through a thermal compression process, a low temperature metal diffusion process, or through surface activated bonding.

Various embodiments of wearable electronic device 10 provide several advantages, at least some of which are unexpected. For example, according to several embodiments voltage reference plane 36 improves electrical signaling integrity in wearable electronic device 10 compared to a wearable electronic device that doesn't include voltage reference plane 36. Additionally, voltage reference plane 36 may help to reduce the x-y form-factor of wearable electronic device 10.

As illustrated in FIG. 1, voltage reference plane 36 substantially covers first silicon die 20, second silicon die 22, and transmission line 26. This may help to enable radio-frequency (RF) device integration that enhances the device functionality of wearable electronic device 10 by providing shielding against electromagnetic interference and radio-frequency interference to the dies 20, 22, and transmission line 26. Additionally, voltage reference plane 36 may help to ensure a robust signal electric current return path and improved impedance control for transmission line 26 in wearable electronic device 10. This may help to increase overall electrical performance of wearable electronic device 10. The low profile textile-based packaging solution may help to further reduce the overall weight of wearable electronic device 10 by eliminating bulky electronic components e.g. multilayer organic package substrate and/or printed circuit boards (PCBs).

FIG. 5 illustrates a system level diagram, according to an embodiment of the wearable electronic device 10. In an embodiment, system 100 includes, but is not limited to, a personal digital assistant (PDA), a mobile workstation, a fitness tracker, a global positioning system, an Internet appliance or any other type of computing device. In some embodiments, system 100 is a system on a chip (SOC) system.

In an embodiment, processor 110 has one or more processing cores 112 and 112N, where 112N represents the Nth processor core inside processor 110 where N is a positive integer. In an embodiment, system 100 includes multiple processors including 110 and 105, where processor 105 has logic similar or identical to the logic of processor 110. In some embodiments, processing core 112 includes, but is not limited to, pre-fetch logic to fetch instructions, decode logic to decode the instructions, execution logic to execute instructions and the like. In some embodiments, processor 110 has a cache memory 116 to cache instructions and/or data for system 100. Cache memory 116 may be organized into a hierarchal structure including one or more levels of cache memory.

In some embodiments, processor 110 includes a memory controller 114, which is operable to perform functions that enable the processor 110 to access and communicate with memory 130 that includes a volatile memory 132 and/or a non-volatile memory 134. In some embodiments, processor 110 is coupled with memory 130 and chipset 120. Processor 110 may also be coupled to a wireless antenna 178 to communicate with any device configured to transmit and/or receive wireless signals. In an embodiment, the wireless antenna interface 178 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 132 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 134 includes, but is not limited to, flash memory, phase change memory (PCM), read-only memory (ROM), electrically erasable programmable read-only memory (EEPROM), or any other type of non-volatile memory device.

Memory 130 stores information and instructions to be executed by processor 110. In an embodiment, memory 130 may also store temporary variables or other intermediate information while processor 110 is executing instructions. In the illustrated embodiment, chipset 120 connects with processor 110 via Point-to-Point (PtP or P-P) interfaces 117 and 122. Chipset 120 enables processor 110 to connect to other elements in system 100. In some embodiments of the invention, interfaces 117 and 122 operate in accordance with a PtP communication protocol such as the Intel® QuickPath Interconnect (QPI) or the like. In other embodiments, a different interconnect may be used.

In some embodiments, chipset 120 is operable to communicate with processor 110, 105N, display device 140, and other devices 172, 176, 174, 160, 162, 164, 166, 177, etc. Chipset 120 may also be coupled to a wireless antenna 178 to communicate with any device configured to transmit and/or receive wireless signals.

Chipset 120 connects to display device 140 via interface 126. Display 140 may be, for example, a liquid crystal display (LCD), a plasma display, cathode ray tube (CRT) display, or any other form of visual display device. In some embodiments of the invention, processor 110 and chipset 120 are merged into a single SOC. In addition, chipset 120 connects to one or more buses 150 and 155 that interconnect various elements 174, 160, 162, 164, and 166. Buses 150 and 155 may be interconnected together via a bus bridge 172.

In an embodiment, mass storage device 162 includes, but is not limited to, a solid state drive, a hard disk drive, a universal serial bus flash memory drive, or any other form of computer data storage medium. In an embodiment, network interface 166 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In an embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 100, the functions performed by some of these blocks may be integrated within a single semiconductor circuit or may be implemented using two or more separate integrated circuits. For example, although cache memory 116 is depicted as a separate block within processor 110, cache memory 116 (or selected aspects of 116) may be incorporated into processor core 112.

### Additional Embodiments

The following exemplary embodiments are provided, the numbering of which is not to be construed as designating levels of importance:

Embodiment 1 a wearable electronic device comprising:

a first flexible layer comprising:
a first surface;
a second surface substantially parallel to the first surface;

a first electrical component attached to the second surface;

a second electrical component attached to the second surface;

a transmission line connecting the first electrical component and the second electrical component; and

a voltage reference trace connected to a voltage reference source in at least one of the first electrical component or the second electrical component;

a second flexible layer comprising:
a third surface substantially parallel to the second surface and facing the second surface;
a fourth surface;

a voltage reference plane attached to the third surface; and

an interconnection formed between the voltage reference trace and the voltage reference plane.

Embodiment 2 the wearable electronic device of Embodiment 1, wherein the first flexible layer comprises a fabric material.

Embodiment 3 the wearable electronic device of any one of Embodiments 1-2, wherein the first flexible layer comprises a textile material.

Embodiment 4 the wearable electronic device of any one of Embodiments 1-3, wherein the first flexible layer comprises a mixture of fabric material and textile material.

Embodiment 5 the wearable electronic device of any one of Embodiments 1-4, wherein the second flexible layer comprises a fabric material.

Embodiment 6 the wearable electronic device of any one of Embodiments 1-5, wherein the second flexible layer comprises a textile material.

Embodiment 7 the wearable electronic device of any one of Embodiments 1-6, wherein the second flexible layer comprises a mixture of fabric material and textile material.

Embodiment 8 the wearable electronic device of any one of Embodiments 1-7, wherein the first electrical component is a silicon die.

Embodiment 9 the wearable electronic device of any one of Embodiments 1-8, wherein the electrical component is selected from the group consisting of, a central processing unit, a flash memory, a Wi-Fi transmitter, and a global positioning system.

Embodiment 10 the wearable electronic device of any one of Embodiments 1-9, wherein the second electrical component is a silicon die.

Embodiment 11 the wearable electronic device of any one of Embodiments 1-10, wherein the electrical component is selected from the group consisting of, a central processing unit, a flash memory, a Wi-Fi transmitter, and a global positioning system.

Embodiment 12 the wearable electronic device of any one of Embodiments 1-11, wherein the transmission line is formed from a conductive material.

Embodiment 13 the wearable electronic device of any one of Embodiments 1-12, wherein the conductive material is selected from the group consisting of, a metal, conductive ink, and combinations thereof.

Embodiment 14 the wearable electronic device of any one of Embodiments 1-13, wherein the voltage reference plane is formed from a conductive material.

Embodiment 15 the wearable electronic device of any one of Embodiments 1-14, wherein the conductive material is selected from the group consisting of, a metal, conductive ink, and combinations thereof.

Embodiment 16 the wearable electronic device of any one of Embodiments 1-15, and further comprising:

a power (Vcc) source connected to the voltage reference trace and the voltage reference plane.

Embodiment 17 the wearable electronic device of any one of Embodiments 1-16, wherein the voltage reference plane is a power reference plane.

Embodiment 18 the wearable electronic device of any one of Embodiments 1-17, and further comprising:

a ground (Vss) source connected to the voltage reference trace and the voltage reference plane

Embodiment 19 the wearable electronic device of any one of Embodiments 1-18, wherein the voltage reference plane is a ground reference plane.

Embodiment 20 the wearable electronic device of any one of Embodiments 1-19, and further comprising:

an interface formed by the interconnection between the voltage reference trace and the voltage reference plane.

Embodiment 21 the wearable electronic device of any one of Embodiments 1-20, wherein the voltage reference trace and the voltage reference plane are in direct contact at the interface.

Embodiment 22 the wearable electronic device of any one of Embodiments 1-21, wherein the voltage reference trace and the voltage reference plane are joined at the interface by thermal compression.

Embodiment 23 the wearable electronic device of any one of Embodiments 1-22, wherein the voltage reference trace and the voltage reference plane are joined at the interface by low temperature metal diffusion.

Embodiment 24 the wearable electronic device of any one of Embodiments 1-23, wherein the voltage reference trace and the voltage reference plane are joined at the interface by surface activated bonding.

Embodiment 25 the wearable electronic device of any one of Embodiments 1-24, wherein a length of the transmission line and a length of the voltage reference plane are substantially equivalent.

Embodiment 26 the wearable electronic device of any one of Embodiments 1-25, wherein a major portion of the voltage reference plane is parallel to a major portion of the second surface of the first flexible layer.

Embodiment 27 the wearable electronic device of any one of Embodiments 1-26, wherein a major portion of the voltage reference plane covers at least a portion of the second surface of the first flexible layer.

Embodiment 28 the wearable electronic device of any one of Embodiments 1-27, wherein the portion of the second surface of the first flexible layer comprises the first electrical component, the second electrical component, and the transmission line.

Embodiment 29 the wearable electronic device of any one of Embodiments 1-28, wherein the voltage reference plane is continuous.

Embodiment 30 the wearable electronic device of any one of Embodiments 1-29, wherein the voltage reference plane includes cut out section.

Embodiment 31 the wearable electronic device of any one of Embodiments 1-30, wherein the cutout is sized to allow a portion of at least one of the first or second electrical components to at least partially exposed through the cut out.

Embodiment 32 the wearable electronic device of any one of Embodiments 1-31, wherein the electrical component at least partially exposed through the cut out is a transmitter die.

Embodiment 33 the wearable electronic device of any one of Embodiments 1-32, wherein transmitter die is selected from the group consisting of, a WiFi, a radio, a wireless charger, a GPS, and combinations thereof.

Embodiment 34 the wearable electronic device of any one of Embodiments 1-33, wherein the voltage reference plane improves electrical signaling integrity compared to a wearable electronic device that is free of a voltage reference plane.

Embodiment 35 the wearable electronic device of any one of Embodiments 1-34, wherein the voltage reference plane improves electrical signaling by providing shielding against electromagnetic interference to the electrical components and the transmission line.

Embodiment 36 the wearable electronic device of any one of Embodiments 1-35, wherein the voltage reference plane improves electrical signaling by providing shielding against radio-frequency interference to the electrical components and the transmission line.

Embodiment 37 the wearable electronic device of any one of Embodiments 1-36, wherein a thickness of the voltage reference plane ranges from about 10 microns to about 20 microns.

Embodiment 38 the wearable electronic device of any one of Embodiments 1-37, wherein a thickness of the transmission line ranges from about 10 microns to about 12 microns.

Embodiment 39 the wearable electronic device of any one of Embodiments 1-38, wherein a thickness of the die ranges from about 20 microns to about 40 microns.

Embodiment 40 the wearable electronic device of any one of Embodiments 1-39, wherein a thickness of the device ranges from about 50 microns to about 80 microns.

Embodiment 41 the wearable electronic device of any one of Embodiments 1-40, and further comprising:

a dielectric layer disposed between the first flexible layer and the second flexible layer.

Embodiment 42 the wearable electronic device of any one of Embodiments 1-41, wherein the dielectric layer comprises a polyimide, a polyimide, a bismaleimide-triazine (BT) resin, epoxy resin, polyurethanes, benzocyclobutene (BCB), a high-density polyethylene (HDPE), and combinations thereof.

Embodiment 43 the wearable electronic device of any one of Embodiments 1-42, wherein interface is substantially free of dielectric materials

Embodiment 44 the wearable electronic device of any one of Embodiments 1-43, and further comprising:

a first water resistant encapsulant layer disposed between the first flexible layer and the transmission line.

Embodiment 45 the wearable electronic device of any one of Embodiments 1-44, and further comprising:

a second water resistant encapsulant layer disposed between the second flexible layer and the voltage reference plane.

Embodiment 46 the wearable electronic device of any one of Embodiments 1-45, wherein the first water resistant encapsulant layer and the second water resistant encapsulant layer comprise a water resistant material.

Embodiment 47 the wearable electronic device of any one of Embodiments 1-46, wherein the water resistant material is selected from the group consisting of, silicone elastomers, fluoropolymers, rubbers, polyvinyl chloride, polyurethane, wax, and combinations thereof.

Embodiment 48 the wearable electronic device of any one of Embodiments 1-47, wherein the interface is substantially free of the water resistant encapsulant layer.

Embodiment 49 the wearable electronic device of any one of Embodiments 1-48, and further comprising:

a third electrical component attached to the third surface;

a fourth electrical component attached to the third surface; and

a second transmission line connecting the third electrical component and the fourth electrical component;
wherein the third electrical component, fourth electrical component and the transmission line are located between the third surface and the voltage reference plane.

Embodiment 50 the wearable electronic device of any one of Embodiments 1-49, and further comprising:

a second dielectric layer located between the third surface and each of the third electrical component, fourth electrical component, and transmission line.

Embodiment 51 the wearable electronic device of any one of Embodiments 1-50, and further comprising:

an adhesive layer disposed on at least one of the first surface and the fourth surface.

Embodiment 52 an article of clothing comprising:

the wearable electronic device of any one of Embodiments 1-51.

Embodiment 53 the article of clothing of any one of Embodiments 1-52, wherein the clothing comprises a fabric material.

Embodiment 54 the article of clothing of any one of Embodiments 1-53, wherein the clothing comprises a textile material.

Embodiment 55 the article of clothing of any one of Embodiments 1-54, wherein the wearable electronic device is integral to the clothing.

Embodiment 56 the article of clothing of any one of Embodiments 1-55, wherein the wearable electronic device is sewn into the clothing.

Embodiment 57 the article of clothing of any one of Embodiments 1-56, wherein the wearable electronic device is adhered to the clothing.

Embodiment 58 a skin patch comprising:

the wearable electronic device of any one of Embodiments 1-57.

Embodiment 59 the skin patch of any one of Embodiments 1-58, wherein the skin patch is a fabric material.

Embodiment 60 the skin patch of any one of Embodiments 1-59, wherein the skin patch is a textile material.

Embodiment 61 an electronic device comprising:

a first flexible layer comprising:
a first surface;
a second surface substantially parallel to the first surface;

a first electrical component attached to the second surface;

a second electrical component attached to the second surface;

a transmission line connecting the first electrical component and the second electrical component; and

a voltage reference trace connected to a voltage reference source in at least one of the first electrical component or the second electrical component;

a second flexible layer comprising:
a third surface substantially parallel to the second surface and facing the second surface;
a fourth surface;

a voltage reference plane attached to the third surface;

a dielectric layer disposed between the first flexible layer and the second flexible layer;

an interconnection formed between the voltage reference trace and the voltage reference plane;

a first water resistant encapsulant layer disposed between the first layer and the transmission line; and

a second water resistant encapsulant layer disposed between the second layer and the voltage reference plane;

wherein the first layer and the second layer are formed from at least one of a fabric or a textile material.

Embodiment 62 the electronic device of Embodiment 61 wherein the dielectric layer comprises a polyimide, a polyimide, a bismaleimide-triazine (BT) resin, epoxy resin, polyurethanes, benzocyclobutene (BCB), a high-density polyethylene (HDPE), and combinations thereof.

Embodiment 63 the electronic device of any one of Embodiments 61-62, wherein interface is substantially free of dielectric materials

Embodiment 64 the electronic device of any one of Embodiments 61-63, wherein the electrical component is selected from the group consisting of, a central processing unit, a flash memory, a Wi-Fi transmitter, and a global positioning system.

Embodiment 65 the electronic device of any one of Embodiments 61-64, wherein the second electrical component is an electrical component.

Embodiment 66 the electronic device of any one of Embodiments 61-65, wherein the electrical component is selected from the group consisting of, a central processing unit, a flash memory, a Wi-Fi transmitter, and a global positioning system.

Embodiment 67 the electronic device of any one of Embodiments 61-66, wherein the transmission line is formed from a conductive material.

Embodiment 68 the electronic device of any one of Embodiments 61-67, wherein the conductive material is selected from the group consisting of, a metal, conductive ink, and combinations thereof.

Embodiment 69 the electronic device of any one of Embodiments 61-68, wherein the voltage reference plane is formed from a conductive material.

Embodiment 70 the electronic device of any one of Embodiments 61-69, wherein the conductive material is selected from the group consisting of, a metal, conductive ink, and combinations thereof.

Embodiment 71 the electronic device of any one of Embodiments 61-70, and further comprising:

a power (Vcc) source connected to the voltage reference trace and the voltage reference plane.

Embodiment 72 the electronic device of any one of Embodiments 61-71, wherein the voltage reference plane is a power reference plane.

Embodiment 73 the electronic device of any one of Embodiments 61-72, and further comprising:

a ground (Vss) source connected to the voltage reference trace and the voltage reference plane.

Embodiment 74 the electronic device of any one of Embodiments 61-73, wherein the voltage reference plane is a ground reference plane.

Embodiment 75 the electronic device of any one of Embodiments 61-74, and further comprising:

an interface formed by the interconnection between the voltage reference trace and the voltage reference plane.

Embodiment 76 the electronic device of any one of Embodiments 61-75, wherein the voltage reference trace and the voltage reference plane are in direct contact at the interface.

Embodiment 77 the electronic device of any one of Embodiments 61-76, wherein the voltage reference trace and the voltage reference plane are joined at the interface by thermal compression.

Embodiment 78 the electronic device of any one of Embodiments 61-77, wherein the voltage reference trace and the voltage reference plane are joined at the interface by low temperature metal diffusion.

Embodiment 79 the electronic device of any one of Embodiments 61-78, wherein the voltage reference trace and the voltage reference plane are joined at the interface by surface activated bonding.

Embodiment 80 the electronic device of any one of Embodiments 61-79, wherein a length of the transmission line and a length of the voltage reference plane are substantially equivalent.

Embodiment 81 the electronic device of any one of Embodiments 61-80, wherein a major portion of the voltage reference plane is parallel to a major portion of the second surface of the first layer.

Embodiment 82 the electronic device of any one of Embodiments 61-81, wherein a major portion of the voltage reference plane covers at least a portion of the second surface of the first layer.

Embodiment 83 the electronic device of any one of Embodiments 61-82, wherein the portion of the second surface of the first layer comprises the first electrical component, the second electrical component, and the transmission line.

Embodiment 84 the electronic device of any one of Embodiments 61-83, wherein the voltage reference plane is continuous.

Embodiment 85 the electronic device of any one of Embodiments 61-84, wherein the voltage reference plane includes cut out section.

Embodiment 86 the electronic device of any one of Embodiments 61-85, wherein the cutout is sized to allow a portion of at least one of the first or second electrical components to at least partially exposed through the cut out.

Embodiment 87 the electronic device of any one of Embodiments 61-86, wherein the electrical component at least partially exposed through the cut out is a transmitter die.

Embodiment 88 the electronic device of any one of Embodiments 61-87, wherein transmitter die is selected from the group consisting of, a WiFi, a radio, a wireless charger, a GPS, and combinations thereof.

Embodiment 89 the electronic device of any one of Embodiments 61-88, wherein the voltage reference plane improves electrical signaling integrity compared to a wearable electronic device that is free of a voltage reference plane.

Embodiment 90 the electronic device of any one of Embodiments 61-89, wherein the voltage reference plane improves electrical signaling by providing shielding against electromagnetic interference to the electrical components and the transmission line.

Embodiment 91 the electronic device of any one of Embodiments 61-90, wherein the voltage reference plane improves electrical signaling by providing shielding against radio-frequency interference to the electrical components and the transmission line.

Embodiment 92 the electronic device of any one of Embodiments 61-91, wherein a thickness of the voltage reference plane ranges from about 10 microns to about 20 microns.

Embodiment 93 the electronic device of any one of Embodiments 61-92, wherein a thickness of the transmission line ranges from about 10 microns to about 12 microns.

Embodiment 94 the electronic device of any one of Embodiments 61-93, wherein a thickness of the die ranges from about 20 microns to about 40 microns.

Embodiment 95 the electronic device of any one of Embodiments 61-94, wherein a thickness of the device ranges from about 50 microns to about 80 microns.

Embodiment 96 the electronic device of any one of Embodiments 61-95, and further comprising:

a third electrical component attached to the third surface;

a fourth electrical component attached to the third surface; and

a second transmission line connecting the third electrical component and the fourth electrical component;

wherein the third electrical component, fourth electrical component and the transmission line are located between the third surface and the voltage reference plane.

Embodiment 97 the electronic device of any one of Embodiments 61-97, and further comprising:

a second dielectric layer located between the third surface and each of the third electrical component, fourth electrical component, and transmission line.

Embodiment 98. A method of forming a wearable electronic device comprising:

attaching a first flexible layer to a plurality of conductive traces;

attaching a plurality of dies to at least one of the plurality of traces;

attaching a second flexible layer to a voltage reference plane;

attaching a portion of the voltage reference plane to a dielectric material to form a first portion covered by the dielectric material and an adjacent second portion free of the dielectric material;

aligning the second portion of voltage reference plane with one of the plurality of traces; and

compressing the first flexible layer and the second flexible layer to form an interconnect between the second portion of the voltage reference plane and the trace.

Embodiment 99. The method of Embodiment 98 and further comprising:

forming a water resistant layer between the plurality of traces and the first flexible layer.

Embodiment 100 the method of any one of Embodiments 98-99 and further comprising:

forming a water resistant layer between the second flexible layer and voltage reference plane.

Embodiment 101 the method of any one of Embodiments 98-100, wherein the portion of the voltage reference plane contacted by the dielectric material is 80 percent to 99 percent of voltage reference plane.

Embodiment 102 the method of any one of Embodiments 98-101, wherein the portion of the voltage reference plane contacted by the dielectric material is 85 percent to 95 percent of voltage reference plane.

Embodiment 103 the method of any one of Embodiments 98-102, wherein the plurality of traces are attached to the first flexible layer by stamping or metal ink printing.

Embodiment 104 the method of any one of Embodiments 98-103, wherein the plurality of dies are attached to the traces by low temperature metal diffusion.

Embodiment 105 the method of any one of Embodiments 98-104, wherein the low temperature metal diffusion is carried out at a temperature below 200° F.

Embodiment 106 the method of any one of Embodiments 98-105, wherein the voltage reference plane is attached to the second flexible layer through lamination or stamping process.

Embodiment 107 the method of any one of Embodiments 98-106, wherein at least one of the first flexible layer and the second flexible layer is formed from a fabric material.

Embodiment 108 the method of any one of Embodiments 98-107, wherein at least one of the first flexible layer and the second flexible layer is formed from a textile material.

Embodiment 109 the method of any one of Embodiments 98-108, and further comprising:

applying an adhesive layer to at least one of the first flexible layer and the second flexible layer.

Embodiment 110 the method of any one of Embodiments 98-109, wherein at least one of the plurality of traces and the voltage reference plane are joined at the interface by thermal compression.

Embodiment 111 the method of any one of Embodiments 98-110, wherein at least one of the plurality of traces and the voltage reference plane are joined at the interface by low temperature metal diffusion.

Embodiment 112 the method of any one of Embodiments 98-111, wherein at least one of the plurality of traces and the voltage reference plane are joined at the interface by surface activated bonding.

1. A wearable electronic device comprising:
a first flexible layer comprising:
a first surface;
a second surface substantially parallel to the first surface;
a first electrical component attached to the second surface;
a second electrical component attached to the second surface;
a transmission line connecting the first electrical component and the second electrical component; and
a voltage reference trace connected to a voltage reference source attached to at least one of the first electrical component or the second electrical component;
a second flexible layer attached to the first flexible layer to form a laminate, the second flexible layer comprising:
a third surface substantially parallel to the second surface and facing the second surface;
a fourth surface;
a voltage reference plane attached to the third surface; and
an interconnection formed between the voltage reference trace and the voltage reference plane.

2. The wearable electronic device of claim 1, wherein the first flexible layer comprises a fabric material.

3. The wearable electronic device of claim 1, wherein the first flexible layer comprises a textile material.

4. The wearable electronic device of claim 1, wherein the second flexible layer comprises a fabric material.

5. The wearable electronic device of claim 1, wherein the second flexible layer comprises a textile material.

6. The wearable electronic device of claim 1, wherein at least one of the first electrical component and the second electrical component is a silicon die.

7. The wearable electronic device of claim 1, wherein the voltage reference plane is formed from a conductive material is selected from the group consisting of, a metal, conductive ink, and combinations thereof.

8. The wearable electronic device of claim 7, wherein the voltage reference trace and the voltage reference plane are in direct contact at an interface.

9. The wearable electronic device of claim 1, wherein a length of the transmission line and a length of the voltage reference plane are substantially equivalent.

10. The wearable electronic device of claim 1, wherein a major portion of the voltage reference plane is parallel to a major portion of the second surface of the first flexible layer.

11. The wearable electronic device of claim 1, wherein a major portion of the voltage reference plane covers at least a portion of the second surface of the first flexible layer.

12. An electronic device comprising:
a first flexible layer comprising:
a first surface;
a second surface substantially parallel to the first surface;
a first electrical component attached to the second surface;
a second electrical component attached to the second surface;
a transmission line connecting the first electrical component and the second electrical component; and
a voltage reference trace connected to a voltage reference source attached to at least one of the first electrical component or the second electrical component;
a second layer attached to the first flexible layer to form a laminate, the second flexible layer comprising:
a third surface substantially parallel to the second surface and facing the second surface;
a fourth surface;
a voltage reference plane attached to the third surface;
a dielectric layer disposed between the first layer and the second layer;
an interconnection formed between the voltage reference trace and the voltage reference plane;
a first water resistant encapsulant layer disposed between the first flexible layer and the transmission line; and
a second water resistant encapsulant layer disposed between the second flexible layer and the voltage reference plane;
wherein the first flexible layer and the second flexible layer are formed from at least one of a fabric or a textile material.

13. The electronic device of claim 13, and further comprising:
an interface formed by the interconnection between the voltage reference trace and the voltage reference plane.

14. The electronic device of claim 13, wherein the voltage reference trace and the voltage reference plane are in direct contact at the interface.

15. A method of forming a wearable electronic device comprising:
attaching a first flexible layer to a plurality of conductive traces;
attaching a plurality of dies to at least one of the plurality of traces;
attaching a second flexible layer to a voltage reference plane;
attaching a portion of the voltage reference plane to a dielectric material to form a first portion covered by the dielectric material and an adjacent second portion free of the dielectric material;
aligning the second portion of voltage reference plane with one of the plurality of traces; and
compressing the first flexible layer and the second flexible layer to form an interconnect between the second portion of the voltage reference plane and the trace.

16. The method of claim 15 and further comprising:
forming a water resistant layer between the plurality of traces and the first flexible layer.

17. The method of claim 15 and further comprising:
forming a water resistant layer between the second flexible layer and voltage reference plane.

18. The method of claim 15, wherein the portion of the voltage reference plane contacted by the dielectric material is 80 percent to 99 percent of voltage reference plane.

19. The method of claim 18, wherein the portion of the voltage reference plane contacted by the dielectric material is 85 percent to 95 percent of voltage reference plane.

20. The method of claim 15, and further comprising:
applying an adhesive layer to at least one of the first flexible layer and the second flexible layer.
